(19) United States
(12) Patent Application Publication
(10) Pub. No.: US 2016/0087188 A1
(43) Pub. Date: Mar. 24, 2016

(54) SENSING DEVICE

(71) Applicant: Primax Electronics Ltd., Taipei (TW)

(72) Inventor: TSUNG-HUI CHAO, Taipei (TW)

(21) Appl. No.: 14/524,265

(22) Filed: Oct. 27, 2014

(30) Foreign Application Priority Data
Sep. 19, 2014 (TW) 103132391

(51) Int. Cl. H01L 41/053; H01L 41/047; H01L 41/083; H01L 27/20; H01L 41/113

(52) U.S. Cl. CPC H01L 41/0533; H01L 27/20; H01L 41/1132; H01L 41/083; H01L 41/0471; H01L 41/0472

(57) ABSTRACT

A sensing device is provided for acquiring a surface image of an object. The sensing device includes a protective layer, a conductive material layer under the protective layer, a first conductive film layer under the conductive material layer, a sensing layer under the first conductive film layer and a substrate under the sensing layer. When a surface of the object is pressed on the protective layer, a sensing signal is transmitted from the sensing layer to the surface of the object and a reflecting signal reflected from the surface of the object is received by the sensing layer. Then, a current signal corresponding to the reflecting signal is transmitted from the substrate to a central processing unit through the first conductive film layer. Consequently, the current signal is converted into the surface image of the object by the central processing unit.

### FIELD OF THE INVENTION

The present invention relates to a sensing device, and more particularly to a sensing device for acquiring a surface image of an object.

### BACKGROUND OF THE INVENTION

An object surface image sensing device is mainly used to acquire the complete surface image of an object. Generally, the object surface image sensing device is classified into two types, i.e. a semiconductor chip type and an optical type.

The sensing technology applied to the semiconductor chip type sensing device includes for example a capacitive sensing technology, a pressure sensing technology or a thermal sensing technology. According to the capacitive sensing technology, a high-density micro capacitive sensor is integrated into a chip. When a fingerprint is pressed on the surface of the chip, the high-density micro capacitive sensor within the chip may generate different amounts of charges according to the concave and convex structures of the surface of the object. Consequently, the surface image of the object is generated.

The capacitive sensing device has the advantages of slimness and miniaturization. However, the capacitive sensing device has the disadvantages of high cost and low durability. In particular, for maintaining a required pressing area of the capacitive sensing device, it is necessary to cut a whole wafer. Consequently, the cost of producing each chip is very high. Moreover, since the capacitive sensing device itself is a bare chip, it is a designing challenge to prevent the object from eroding the chip surface and provide the electrostatic protection.

In the optical sensing device, a light source, a triangular prism and a camera module are assembled as a set of object surface image pickup equipment. After the triangular prism is pressed by the object, the light beams are reflected or absorbed by the concave and convex structures of the surface of the object. Consequently, the surface image of the object is obtained by the camera module.

The optical sensing device acquires the surface image of the object without the need of touching the chip. That is, the position to be pressed by the object is made of acrylic resin, glass or other optical element. Consequently, the optical sensing device has the advantages of cost-effectiveness and durability. However, the optical sensing device is sensitive to light. The strong natural light may result in a failed image or an incomplete image. Moreover, it is difficult for the optical sensing device to accurately capture the surface image of a contaminated object.

Therefore, there is a need of providing an improved object surface image sensing device in order to overcome the above drawbacks.

### SUMMARY OF THE INVENTION

An object of the present invention provides an ultrasonic-type object surface image sensing device, which is durable and capable of accurately capturing a surface image of a contaminated object.

In accordance with an aspect of the present invention, there is provided a sensing device for acquiring a surface image of an object. The sensing device includes a protective layer, a conductive material layer, a first conductive film layer, a sensing layer and a substrate. The protective layer is contacted with a surface of the object. The conductive material layer is disposed under the protective layer, and increases a conductivity of the sensing device. The conductive material layer is protected by the protective layer. The first conductive film layer is disposed under the conductive material layer. The sensing layer is disposed under the first conductive film layer. A sensing signal is transmitted from the sensing layer to the surface of the object. Moreover, a reflecting signal reflected from the surface of the object is received by the sensing layer. The substrate is disposed under the sensing layer. A current signal corresponding to the reflecting signal is transmitted from the substrate to the first conductive film layer, so that the current signal is converted into the surface image of the object.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic cross-sectional view illustrating a sensing device according to a first embodiment of the present invention;

FIG. 2 is a schematic exploded view illustrating a sensing layer and a substrate of the sensing device according to the first embodiment of the present invention;

FIG. 3 is a flowchart illustrating the operations of the sensing device according to the first embodiment of the present invention;

FIG. 4 is a schematic functional block diagram of the sensing device according to the first embodiment of the present invention;

FIG. 5 is a schematic cross-sectional view illustrating a sensing device according to a second embodiment of the present invention; and

FIG. 6 is a schematic functional block diagram of the sensing device according to the second embodiment of the present invention.

### DETAILED DESCRIPTION OF THE PREFERRED EMBODIMENT

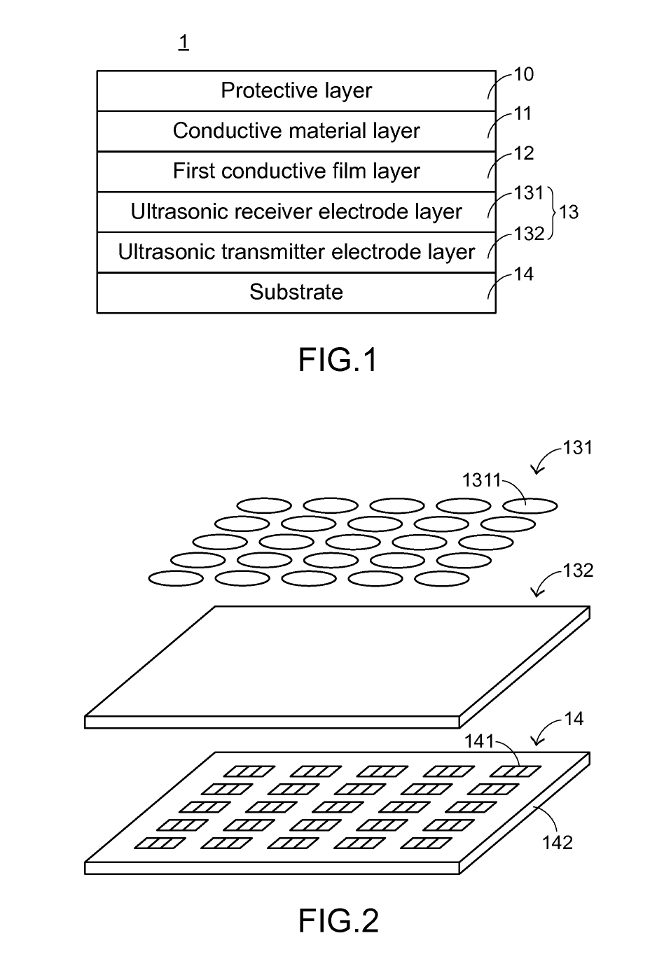

In a first embodiment of the present invention, a sensing device 1 is provided for capturing a surface image of an object. Hereinafter, the components of a sensing device 1 with reference to FIGS. 1 and 2. FIG. 1 is a schematic cross-sectional view illustrating a sensing device according to a first embodiment of the present invention. FIG. 2 is a schematic exploded view illustrating a sensing layer and a substrate of the sensing device according to the first embodiment of the present invention.

The sensing device 1 comprises a protective layer 10, a conductive material layer 11, a first conductive film layer 12, a sensing layer 13 and a substrate 14. The sensing layer 13 comprises an ultrasonic receiver electrode layer 131 and an ultrasonic transmitter electrode layer 132.

In this embodiment, the protective layer 10 is made of a plastic material or a glass material. The protective layer 10 is used for withstanding a pressing action of a surface of an object and protecting the conductive material layer 11. An example of the plastic material includes but is not limited to polyethylene terephthalate (PET), polymethyl methacrylate (PMMA), polycarbonate (PC) or polyurethanes (PU).

The conductive material layer 11 is disposed under the protective layer 10. In addition, the conductive material layer 11 is a conductive film layer, a metallic material layer or a conductive binder layer for increasing the conductivity of the sensing device 1. The conductive material layer 11 is made of a conductive material. An example of the conductive layer includes but is not limited to indium tin oxide (ITO), graphene, metal mesh or silver solder.

The first conductive film layer 12 is disposed under the conductive material layer 11. For example, the first conductive film layer 12 is a polyvinylidene fluoride (PVDF) polymeric film. PVDF is a polymeric material with a high dielectric constant (e.g. up to 10). As is well known to those skilled in the art, the term “dielectric constant” indicates the relative capability of storing electrostatic energy in an electric field by a dielectric material. Consequently, the first conductive film layer 12 is an excellent electrostatic energy storage medium.

The substrate 14 is disposed under the first conductive film layer 12. The ultrasonic transmitter electrode layer 132 and the ultrasonic receiver electrode layer 131 are sequentially formed on the substrate 14. Consequently, the ultrasonic receiver electrode layer 131 is disposed over the ultrasonic transmitter electrode layer 132.

The ultrasonic transmitter electrode layer 132 is used for transmitting a sensing signal to the surface of the object, which is pressed on the protective layer 10. The ultrasonic receiver electrode layer 131 is used for receiving a reflecting signal that is reflected from the surface of the object. In this embodiment, the sensing signal is a planar wave signal, but is not limited thereto.

The detailed structures of the ultrasonic receiver electrode layer 131 and the substrate 14 will be illustrated with reference to FIG. 2. The structures of FIG. 2 are presented herein for purpose of illustration and description only. That is, the structures of the ultrasonic receiver electrode layer 131, the ultrasonic transmitter electrode layer 132 and the substrate 14 are not restricted.

In this embodiment, the substrate 14 is a thin film transistor (TFT) glass substrate. In particular, the substrate 14 comprises plural thin film transistor traces 141 and a glass plate 142. A current signal corresponding to the reflecting signal is transmitted from the substrate 14 to the first conductive film layer 12. The TFT glass substrate is produced by a standard process. Firstly, a metallic or semiconductor thin film is coated on the glass plate 142. Then, a photoresist layer is formed on the metallic or semiconductor thin film. Then, a photomask is used for exposure. Then, an etchant solution is employed to etch off the undesired metallic or semiconductor thin film. After the photoresist layer is removed by a stripper solution, the plural thin film transistor traces 141 are produced. As known, the process of fabricating the TFT glass substrate is cost-effective and successfully applied to the fabricating process of a display panel. Consequently, the application of the process of fabricating the TFT glass substrate to the sensing device 1 of the present invention can reduce the fabricating cost. Moreover, in an embodiment, the ultrasonic transmitter electrode layer 132 and the ultrasonic receiver electrode layer 131 may be sequentially formed on the substrate 14 during the process of producing the substrate 14. Under this circumstance, since the sensing layer 13 and the substrate 14 are collaboratively formed as a sheet-like structure, the process complexity of fabricating the sensing device 1 is reduced.

Please refer to FIG. 2 again. The ultrasonic receiver electrode layer 131 comprises plural ultrasonic receiver units 1311. Each of the plural ultrasonic receiver units 1311 is correlated with a coordinate of the surface of the object. In this embodiment, each of the plural ultrasonic receiver units 1311 is connected with a corresponding thin film transistor trace 141. Each thin film transistor trace 141 may be considered as a switch. When the reflecting signal reflected from the surface of the object is received by the corresponding ultrasonic receiver unit 1311, the generated current signal is transmitted through the corresponding thin film transistor trace 141.

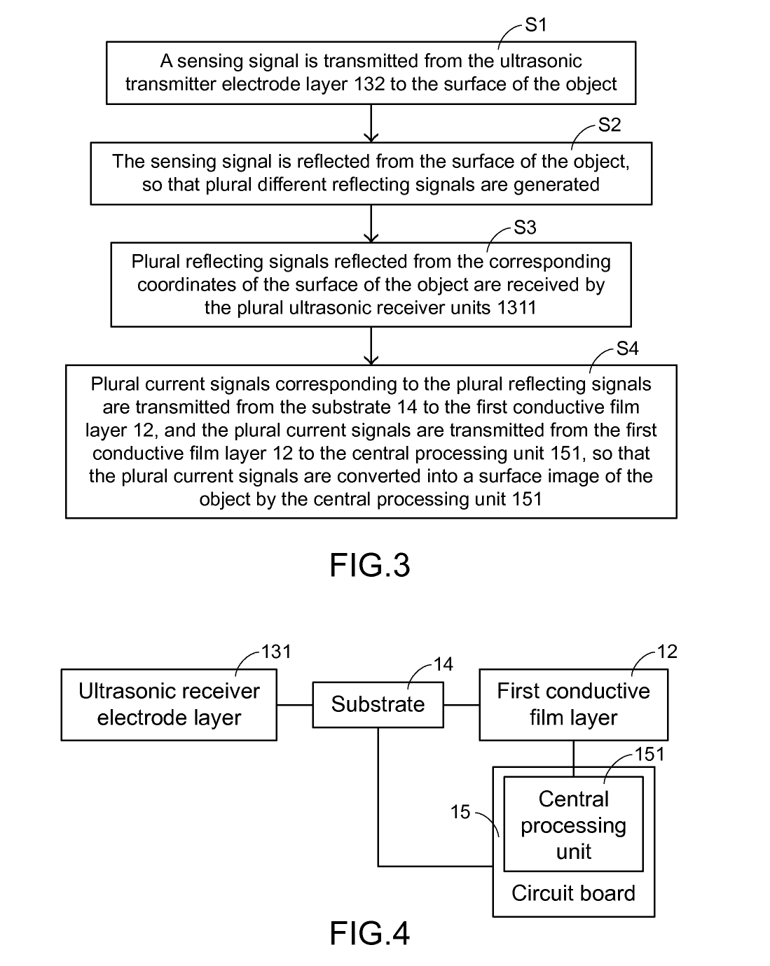

Hereinafter, the operations of the sensing device 1 of this embodiment will be illustrated with reference to FIGS. 3 and 4. FIG. 3 is a flowchart illustrating the operations of the sensing device according to the first embodiment of the present invention. FIG. 4 is a schematic functional block diagram of the sensing device according to the first embodiment of the present invention.

Firstly, when the surface of the object is pressed on the protective layer 10, a sensing signal (e.g. a planar wave signal) is transmitted from the ultrasonic transmitter electrode layer 132 to the surface of the object (Step S1 of FIG. 3). Then, the sensing signal is reflected from the surface of the object, so that plural different reflecting signals are generated (Step S2 of FIG. 3).

In particular, the surface of the object has various textures. That is, the surface of the object has plural concave structures and plural convex structures. The plural concave structures are concaved to different extents. The plural convex structures are raised to different extents. Consequently, the distances between different coordinates of the surface of the object and the ultrasonic transmitter electrode layer 132 are not all identical. In this way, the plural different reflecting signals are generated.

As mentioned above, the ultrasonic receiver electrode layer 131 comprises plural ultrasonic receiver units 1311, and each of the plural ultrasonic receiver units 1311 is correlated with a coordinate of the surface of the object. Consequently, plural reflecting signals reflected from the corresponding coordinates of the surface of the object are received by the plural ultrasonic receiver units 1311 (Step S3).

Please refer to FIGS. 3 and 4. As shown in the step S4 of FIG. 3 and in FIG. 4, the substrate 14 is connected with a circuit board 15, and the first conductive film layer 12 is connected with a central processing unit 151 on the circuit board 15. When the plural reflecting signals are received by the plural ultrasonic receiver units 1311, plural current signals corresponding to the plural reflecting signals are transmitted from the plural thin film transistor traces 141 to the first conductive film layer 12 through the circuit board 15, and the plural current signals are transmitted from the first conductive film layer 12 to the central processing unit 151. As mentioned above, the first conductive film layer 12 is an excellent electrostatic energy storage medium. Since the plural current signals are transmitted from the first conductive film layer 12 to the central processing unit 151, the electrical conductance is effectively enhanced. That is, the resistivity is reduced, and the signal attenuation problem is effectively solved. Under this circumstance, the plural current signals can be transmitted to the central processing unit 151 more completely. Consequently, the efficacy of recognizing the plural current signals by the central processing unit 151 will be increased.

As mentioned above, each of the plural ultrasonic receiver units 1311 is correlated with a coordinate of the surface of the object. Consequently, when the plural current signals are received by the central processing unit 151, the central processing unit 151 may realize the distance between each coordinate of the surface of the object and the ultrasonic transmitter electrode layer 132 according to the intensity of the corresponding current signal. In such way, the surface image of the object can be acquired.

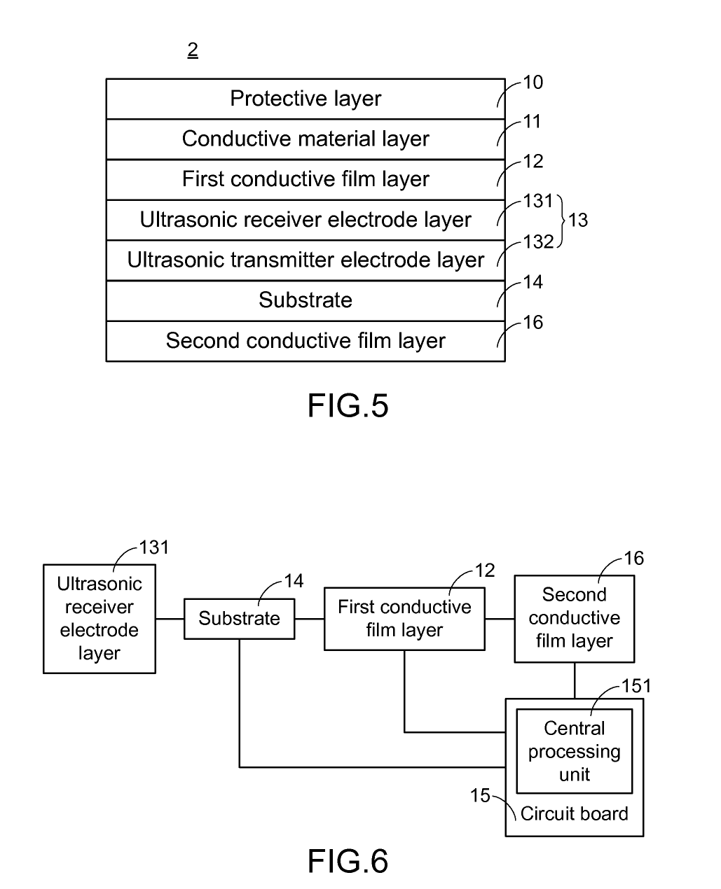

Hereinafter, a sensing device 2 according to a second embodiment of the present invention with reference to FIGS. 5 and 6. FIG. 5 is a schematic cross-sectional view illustrating a sensing device according to a second embodiment of the present invention. FIG. 6 is a schematic functional block diagram of the sensing device according to the second embodiment of the present invention. In comparison with the sensing device 1 of the first embodiment, the sensing device 2 of this embodiment further comprises a second conductive film layer 16. The second conductive film layer 16 is disposed under the substrate 14. The second conductive film layer 16 is connected with the central processing unit 151. The first conductive film layer 12 is connected with the circuit board 15 only, but is not connected with the central processing unit 151. In this embodiment, the plural current signals from the first conductive film layer 12 are received by the second conductive film layer 16 through the circuit board 15, and the plural current signals are transmitted from the second conductive film layer 16 to the central processing unit 151. Since the second conductive film layer 16 has the good capability of storing electrostatic energy, the efficacy of recognizing the plural current signals by the central processing unit 151 will be increased. Moreover, the second conductive film layer 16 is made of the same material as the first conductive film layer 12. The detailed description of the material of the second conductive film layer 16 is omitted.

From the above descriptions, the present invention provides an ultrasonic-type object surface image sensing device. Since the surface of the object is pressed on the protective layer 10 of the sensing device of the present invention rather than the chip, the sensing device of the present invention is more durable than the conventional capacitive sensing device. Moreover, the contamination of the surface of the object may influence the absorption and reflection of the light but not influence the reflection of the ultrasonic wave. Since the sensing device of the present invention is not sensitive to light, the problem of the conventional optical sensing device is eliminated. In addition, the sensing device of the present invention is capable of accurately capturing the surface image of a contaminated object.

In addition to the function of eliminating the drawbacks of the conventional sensing device, the arrangement of the conductive material layer 11, the first conductive film layer 12 and the second conductive film layer 16 can increase the electrical conductance of the sensing device of the present invention. Under this circumstance, the plural current signals can be transmitted to the central processing unit 151 more completely, and thus the efficacy of recognizing the plural current signals by the central processing unit 151 will be increased. Consequently, the surface image of the object is captured in a more precise manner. Moreover, since the ultrasonic receiver electrode layer 131 and the ultrasonic transmitter electrode layer 132 are disposed over the substrate 14, the ultrasonic receiver electrode layer 131 and the ultrasonic transmitter electrode layer 132 are closer to the surface of the object. Under this circumstance, when the plural reflecting signals are received by the ultrasonic receiver electrode layer 131, the signal intensities of the plural current signals are increased. Consequently, the efficacy of recognizing the plural current signals by the central processing unit 151 is increased, and the surface image of the object is captured in a more precise manner.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A sensing device for acquiring a surface image of an object, the sensing device comprising:
a protective layer to be contacted with a surface of the object;
a conductive material layer disposed under the protective layer, wherein a conductivity of the sensing device is increased by the conductive material layer, wherein the conductive material layer is protected by the protective layer;
a first conductive film layer disposed under the conductive material layer;
a sensing layer disposed under the first conductive film layer, wherein a sensing signal is transmitted from the sensing layer to the surface of the object, and a reflecting signal reflected from the surface of the object is received by the sensing layer; and
a substrate disposed under the sensing layer, wherein a current signal corresponding to the reflecting signal is transmitted from the substrate to the first conductive film layer, so that the current signal is converted into the surface image of the object.

2. The sensing device according to claim 1, wherein the first conductive film layer is connected with a circuit board, wherein the current signal is transmitted from the first conductive film layer to a central processing unit on the circuit board, so that the current signal is converted into the surface image of the object by the central processing unit.

3. The sensing device according to claim 1, wherein the sensing layer comprises an ultrasonic receiver electrode layer and an ultrasonic transmitter electrode layer, wherein the ultrasonic receiver electrode layer is disposed over the ultrasonic transmitter electrode layer, wherein the sensing signal is transmitted from the ultrasonic transmitter electrode layer to the surface of the object, and the reflecting signal reflected from the surface of the object is received by the ultrasonic receiver electrode layer.

4. The sensing device according to claim 3, wherein the ultrasonic receiver electrode layer comprises plural ultrasonic receiver units, and each of the plural ultrasonic receiver units is correlated with a coordinate of the surface of the object, wherein when plural reflecting signals reflected from plural coordinates of the surface of the object are received by the corresponding ultrasonic receiver units, plural current signals are generated.

5. The sensing device according to claim 1, wherein the sensing device further comprises a second conductive film layer, wherein the second conductive film layer is disposed under the substrate, and the current signal is transmitted from the first conductive film layer to the second conductive film layer.

6. The sensing device according to claim 5, wherein the first conductive film layer and the second conductive film layer are connected with a circuit board, wherein the current signal is transmitted from the second conductive film layer to a central processing unit on the circuit board, so that the current signal is converted into the surface image of the object by the central processing unit.

7. The sensing device according to claim 5, wherein each of the first conductive film layer and the second conductive film layer is a polyvinylidene fluoride (PVDF) polymeric film.

8. The sensing device according to claim 1, wherein the substrate is a thin film transistor (TFT) glass substrate.

9. The sensing device according to claim 1, wherein the protective layer is made of a plastic material or a glass material.

10. The sensing device according to claim 1, wherein the conductive material layer is a conductive film layer, a metallic material layer or a conductive binder layer.
